(19) United States
(12) Patent Application Publication
(10) Pub. No.: US 2020/0144213 A1
(43) Pub. Date: May 7, 2020

(54) OPTICAL MODULE, OPTICAL COMMUNICATION DEVICE, AND MANUFACTURING METHOD THEREOF

(71) Applicant: FUJITSU LIMITED, Kawasaki-shi (JP)

(72) Inventor: NORIO KAINUMA, Nagano (JP)

(73) Assignee: FUJITSU LIMITED, Kawasaki-shi (JP)

(21) Appl. No.: 16/660,858

(22) Filed: Oct. 23, 2019

(30) Foreign Application Priority Data
Nov. 6, 2018 (JP) 2018-209182

(51) Int. Cl. H01L 23/00; H01S 5/02

(52) U.S. Cl. CPC H01L 24/29; H01S 5/0216; H01L 24/83; H01L 2924/014; H01L 2224/29144; H01L 2224/83395; H01L 2224/29111

(57) ABSTRACT

An optical module includes a semiconductor chip, a first gold-tin layer formed over the semiconductor chip and having gold and tin as main components, a barrier layer formed over the first gold-tin layer, having slower diffusion velocity into tin than diffusion velocity of gold into tin, and having electric conductivity, a second gold-tin layer formed over the barrier layer and having gold and tin as main components, and an optical device provided over the second gold-tin layer.

### CROSS-REFERENCE TO RELATED APPLICATION

This application is based upon and claims the benefit of priority of the prior Japanese Patent Application No. 2018-209182, filed on Nov. 6, 2018, the entire contents of which are incorporated herein by reference.

### FIELD

The embodiment discussed herein is related to an optical module, an optical communication device, and a manufacturing method thereof.

### BACKGROUND

With an increase in amount of data in communication, optical communication devices have been advanced so as to deal with higher frequencies and the larger number of channels. In such a situation, a silicon photonic chip makes it possible to provide an optical communication device with high speed and high density by forming an electric circuit and an optical waveguide over silicon in the same manner as a semiconductor of related art.

On the other hand, it is difficult to enable a silicon photonic chip to emit light due to its material properties, and an optical device that emits light, such as a semiconductor laser, is mounted over a silicon photonic chip by soldering or the like. For soldering the optical device to a semiconductor chip, such as a silicon photonic chip, gold-tin solder containing gold and tin as main components is used, for example.

There has been known a configuration in which an optical semiconductor element is bonded over an optical circuit substrate, a barrier layer made of titanium or the like is formed in an optical semiconductor element mounting portion of the optical circuit substrate, and a gold layer and a tin layer are formed in layers over the barrier layer. There has also been known a configuration in which two or more kinds of solder layers having different melting points and a solder protective layer provided in the uppermost layer of the solder layers are provided in a submount to which a semiconductor element is bonded.

Related art is disclosed in, for example, Japanese Laid-open Patent Publications No. 7-94786 and 2006-278463 and the like.

### SUMMARY

According to an aspect of the embodiments, an optical module includes a semiconductor chip, a first gold-tin layer formed over the semiconductor chip and having gold and tin as main components, a barrier layer formed over the first gold-tin layer, having slower diffusion velocity into tin than diffusion velocity of gold into tin, and having electric conductivity, a second gold-tin layer formed over the barrier layer and having gold and tin as main components, and an optical device provided over the second gold-tin layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram (part 1) illustrating an example of an optical module according to an embodiment;

FIG. 2 is a diagram (part 2) illustrating an example of the optical module according to the embodiment;

FIG. 3 is a diagram illustrating an example of a solder layer of the optical module according to the embodiment;

FIG. 4 is a diagram (part 1) illustrating an example of a manufacturing method of a solder sheet for forming the solder layer of the optical module according to the embodiment;

FIG. 5 is a diagram (part 2) illustrating an example of the manufacturing method of the solder sheet for forming the solder layer of the optical module according to the embodiment;

FIG. 6 is a diagram (part 3) illustrating an example of the manufacturing method of the solder sheet for forming the solder layer of the optical module according to the embodiment;

FIG. 7 is a diagram (part 4) illustrating an example of the manufacturing method of the solder sheet for forming the solder layer of the optical module according to the embodiment;

FIG. 8 is a diagram (part 1) illustrating an example of a manufacturing method of the optical module according to the embodiment;

FIG. 9 is a diagram (part 2) illustrating an example of the manufacturing method of the optical module according to the embodiment;

FIG. 10 is a diagram (part 3) illustrating an example of the manufacturing method of the optical module according to the embodiment;

FIG. 11 is a diagram (part 4) illustrating an example of the manufacturing method of the optical module according to the embodiment;

FIG. 12 is a cross-sectional view illustrating an example of distribution of gold and tin in the solder sheet according to the embodiment;

FIG. 13 is a graph illustrating an example of a relationship between a composition ratio and a melting point in a gold-tin sheet according to the embodiment;

FIG. 14 is a diagram illustrating an example of forming, by plating, a solder layer of the optical module according to the embodiment; and

FIG. 15 is a top view illustrating an example of an optical communication device according to the embodiment.

### DESCRIPTION OF EMBODIMENTS

In the related art described above, for example, when a plurality of optical devices is mounted to a semiconductor chip by soldering by using gold-tin solder, there is a problem that it is difficult to mount each optical device to the semiconductor chip with high accuracy.

For example, since it is difficult to simultaneously mount a plurality of optical devices to a semiconductor chip with high accuracy, the optical devices are mounted to the semiconductor chip one by one. In this case, temperature of the semiconductor chip rises due to heating during soldering of an optical device, and thus a melting point of gold-tin solder for other optical devices being not mounted may rise. This is because gold atoms in gold plating of electrode pads of the semiconductor chip are diffused into the gold-tin solder by heating, for example. When the melting point of the gold-tin solder for an optical device being not mounted is increased, melting of the gold-tin solder becomes difficult, and mounting with high accuracy by soldering of the optical device becomes difficult.

In view of the above, it is desirable to provide an optical module and an optical communication device capable of improving mounting accuracy of an optical device with respect to a semiconductor chip, and to provide a manufacturing method thereof.

Hereinafter, the embodiment of an optical module, an optical communication device, and a manufacturing method thereof according to the present disclosure will be described in detail with reference to the drawings.

### Embodiment

(Optical Module According to Embodiment)

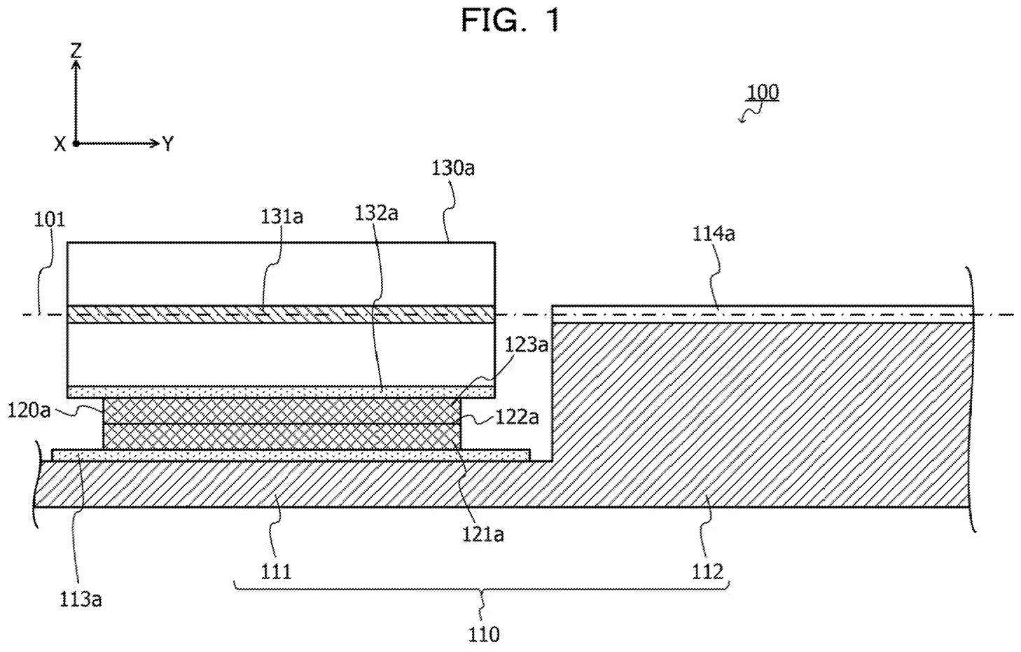

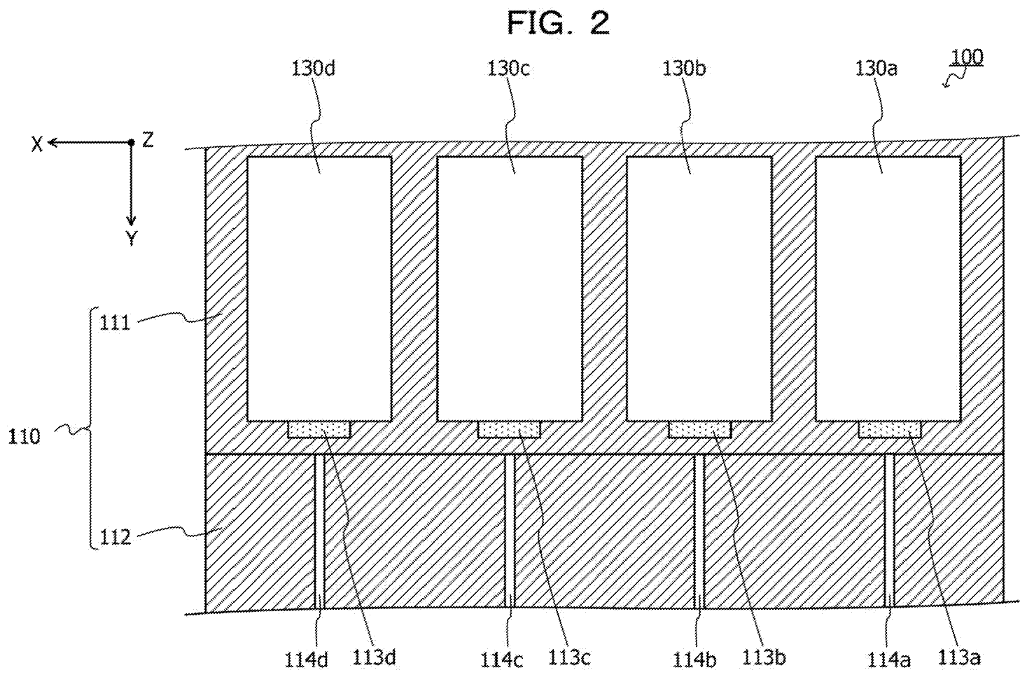

Each of FIG. 1 and FIG. 2 is a diagram illustrating an example of an optical module according to the embodiment. An optical module 100 illustrated in FIG. 1 is a four-channel optical transmission module having channels #1 to #4 as transmission channels. For example, the optical module 100 includes a silicon photonic chip 110 and optical devices 130a to 130d respectively corresponding to the channels #1 to #4.

Each of the optical devices 130a to 130d is, for example, a semiconductor laser, such as a laser diode, which oscillates laser light and emits the oscillated laser light. The optical devices 130a to 130d are arranged in a depth direction in FIG. 1 (in a lateral direction in FIG. 2). Each of the optical devices 130a to 130d emits laser light in a direction orthogonal to an arrangement direction of the optical devices 130a to 130d (a right direction in FIG. 1, a downward direction in FIG. 2).

The arrangement direction of the optical devices 130a to 130d (the depth direction in FIG. 1, the lateral direction in FIG. 2) is defined as an X-axis direction, and an emission direction (a lateral direction in FIG. 1, a longitudinal direction in FIG. 2) of the laser light from each of the optical devices 130a to 130d is defined as a Y-axis direction. A direction orthogonal to the X-axis direction and the Y-axis direction (a longitudinal direction in FIG. 1, a depth direction in FIG. 2) is defined as a Z-axis direction. FIG. 1 illustrates a cross section when the optical module 100 is cut by a YZ plane at a position of the optical device 130a. FIG. 2 illustrates an upper surface of the optical module 100 as viewed from the Z-axis direction.

The silicon photonic chip 110 is a semiconductor chip that is provided by forming a fine optical waveguide structure over a silicon substrate by silicon photonics. For example, the silicon photonic chip 110 includes an optical device mounting portion 111 and an optical waveguide forming portion 112.

The optical device mounting portion 111 is a portion in which the optical devices 130a to 130d are mounted in the silicon photonic chip 110. As illustrated in FIG. 1, a height of a front surface of the optical device mounting portion 111 is lower than a height of a front surface of the optical waveguide forming portion 112. The height here is, for example, a position in the Z-axis direction.

At the front surface of the optical device mounting portion 111, electrode pads 113a to 113d that respectively correspond to the channels #1 to #4 and that are arranged in the X-axis direction are formed. Each of the electrode pads 113a to 113d is an electrode pad containing gold (Au). For example, each of the electrode pads 113a to 113d is formed by plating a front surface of an electric conductor (for example, copper) other than gold, or the like, with gold. Alternatively, the entirety of the electrode pads 113a to 113d may be formed of gold. In both cases, at least a front surface side of each of the electrode pads 113a to 113d is a gold layer made of gold.

The optical waveguide forming portion 112 is a portion in which optical waveguides 114a to 114d respectively corresponding to the channels #1 to #4 are formed in the silicon photonic chip 110. The optical waveguides 114a to 114d are arranged in the X-axis direction near the front surface of the optical waveguide forming portion 112, and individually propagate light in the Y-axis direction. For example, the optical waveguide 114a propagates light emitted from the optical device 130a. Similarly, the optical waveguides 114b to 114d propagate light emitted from the optical devices 130b to 130d, respectively.

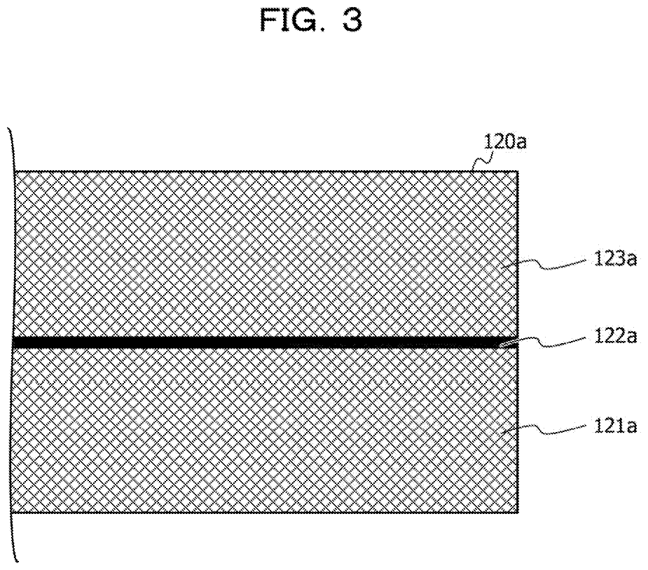

As illustrated in FIG. 1, for example, a solder layer 120a for bonding is provided between the silicon photonic chip 110 and the optical device 130a. The solder layer 120a is formed over the electrode pad 113a, that is, at the front surface side of the electrode pad 113a. The solder layer 120a has a three-layer structure in which a first gold-tin layer 121a, a barrier layer 122a, and a second gold-tin layer 123a are laminated. A structure of the solder layer 120a will be described later (see, for example, FIG. 3). The silicon photonic chip 110 and each of the optical devices 130b to 130d are also bonded with each solder layer similar to the solder layer 120a interposed therebetween.

The optical device 130a is disposed over the solder layer 120a, that is, at a front surface side of the solder layer 120a. For example, an electrode pad 132a is formed over a rear surface of the optical device 130a (a surface at a side of the silicon photonic chip 110). The optical device 130a is disposed such that the electrode pad 132a is in contact with the front surface of the solder layer 120a, is fixed to the optical device mounting portion 111 by the solder layer 120a, and is electrically coupled to the optical device mounting portion 111 by the solder layer 120a.

The optical device 130a includes a light emitting portion 131a that oscillates laser light and that emits the oscillated laser light in the Y-axis direction. A laser light axis 101 illustrated in FIG. 1 is an optical axis of laser light emitted from the light emitting portion 131a. The optical device 130a is mounted to the optical device mounting portion 111 such that light emitted from the light emitting portion 131a is coupled to the optical waveguide 114a and propagates through the optical waveguide 114a. Similarly, the optical devices 130b to 130d are mounted to the optical device mounting portion 111 such that the emitted light is individually coupled to the optical waveguides 114b to 114d and propagates through the optical waveguides 114b to 114d.

(Solder Layer of Optical Module According to Embodiment)

FIG. 3 is a diagram illustrating an example of a solder layer of the optical module according to the embodiment. In FIG. 3, the same portions as those illustrated in FIG. 1 are denoted by the same reference signs and descriptions thereof will be omitted. The solder layer 120a corresponding to the channel #1 will be described, and the respective solder layers corresponding to the channels #2 to #4 are the same as the solder layer 120a. As described above, the solder layer 120a illustrated in FIG. 1 includes the first gold-tin layer 121a, the barrier layer 122a, and the second gold-tin layer 123a.

The first gold-tin layer 121a is formed over the electrode pad 113a of the silicon photonic chip 110 illustrated in FIG. 1, that is, at the front surface side of the electrode pad 113a. The barrier layer 122a is formed over the first gold-tin layer 121a, that is, for example, at a front surface side of the first gold-tin layer 121a. The second gold-tin layer 123a is formed over the barrier layer 122a, that is, for example, at a front surface side of the barrier layer 122a.

The first gold-tin layer 121a is an alloy (electric conductor) containing gold and tin (Sn) as main components. The alloy containing gold and tin as main components is, for example, an alloy having total percentage of gold content and tin content that is equal to or more than 95%, that is, an alloy having content percentage of components other than gold and tin that is less than 5%.

The second gold-tin layer 123a is an alloy (electric conductor) containing gold and tin as main components. Composition of the second gold-tin layer 123a may be the same composition as the first gold-tin layer 121a, and may be different from the composition of the first gold-tin layer 121a as long as gold and tin are main components.

The barrier layer 122a is provided as an intermediate layer between the first gold-tin layer 121a and the second gold-tin layer 123a, among the solder layer 120a. The barrier layer 122a is an electric conductor different from the first gold-tin layer 121a and the second gold-tin layer 123a described above. The barrier layer 122a is formed of a material whose diffusion velocity into tin is slower than diffusion velocity of gold into tin.

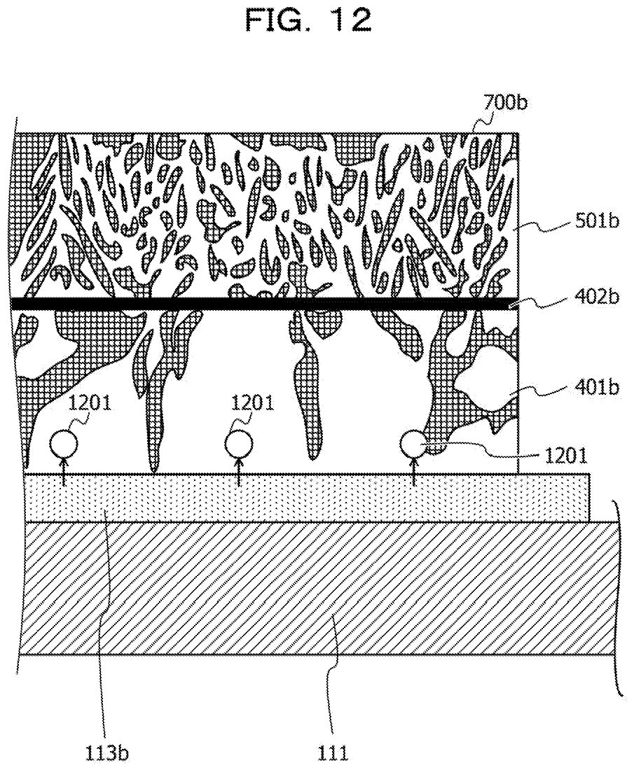

Diffusion velocity of a material (a material other than tin) into tin means velocity at which atoms of the material are diffused into tin by heating the material or the like. Slow diffusion velocity means, for example, that diffusion of atoms by heating or the like is slow, and the atoms are hardly diffused (a diffusion coefficient is low). Diffusion velocity of barrier layer 122a into tin is slower than the diffusion velocity of gold into tin, so that the barrier layer 122a acts as a barrier for suppressing diffusion of gold into the second gold-tin layer 123a to be described later. This point will be described later (for example, see FIG. 12).

A melting point of barrier layer 122a is higher than each of melting points of the first gold-tin layer 121a and the second gold-tin layer 123a. For example, even when the first gold-tin layer 121a and the second gold-tin layer 123a are highly heated and melted, the barrier layer 122a is not melted and the action as a barrier described above of the barrier layer 122a may be maintained.

As an example, nickel (Ni) may be used as a material of the barrier layer 122a that satisfies these conditions. However, as the material of the barrier layer 122a, various electric conductors, such as not only nickel, but also titanium, tungsten, or an alloy containing the same, which have slow diffusion velocity into tin and a high melting point, may be used.

(Manufacturing Method of Solder Sheet for Forming Solder Layer of Optical Module According to Embodiment)

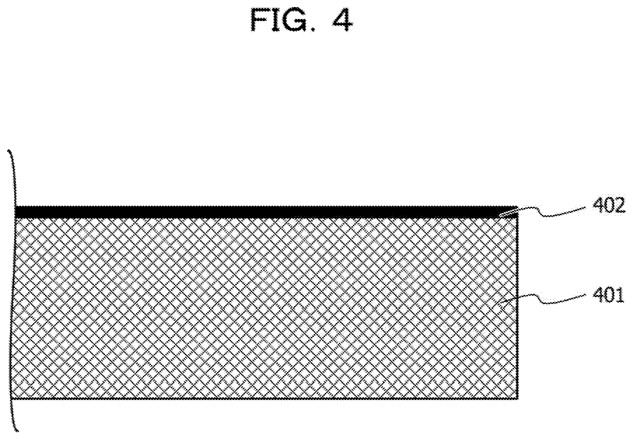

Each of FIG. 4 to FIG. 7 is a diagram illustrating an example of a manufacturing method of a solder sheet for forming a solder layer of the optical module according to the embodiment. The manufacturing method of the solder sheet for forming the solder layer 120a illustrated in FIG. 3 will be described. First, as illustrated in FIG. 4, a first gold-tin sheet 401 to be the first gold-tin layer 121a illustrated in FIG. 3 is prepared. The first gold-tin sheet 401 is a sheet-shaped alloy having gold and tin as main components, as an example, a sheet-shaped alloy having gold content of 80% and tin content of 20%.

Next, as illustrated in FIG. 4, a barrier layer 402 to be the barrier layer 122a illustrated in FIG. 3 is formed at a front surface of the first gold-tin sheet 401. The barrier layer 402 may be formed by forming the above-described layer using nickel or the like, for example, by plating or sputtering. Alternatively, the barrier layer 402 may be formed by disposing the sheet-shaped nickel or the like at the front surface of the first gold-tin sheet 401.

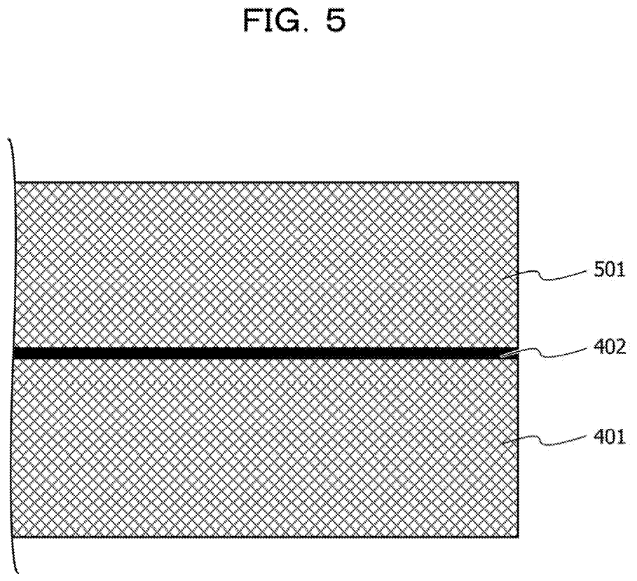

Next, as illustrated in FIG. 5, a second gold-tin sheet 501 as the second gold-tin layer 123a illustrated in FIG. 3 is disposed at a front surface of the barrier layer 402. The second gold-tin sheet 501 is a sheet-shaped alloy having gold and tin as main components, as an example, a sheet-shaped alloy having gold content of 80% and tin content of 20%. However, composition of the second gold-tin sheet 501 may be different from composition of the first gold-tin sheet 401 as long as gold and tin are main components.

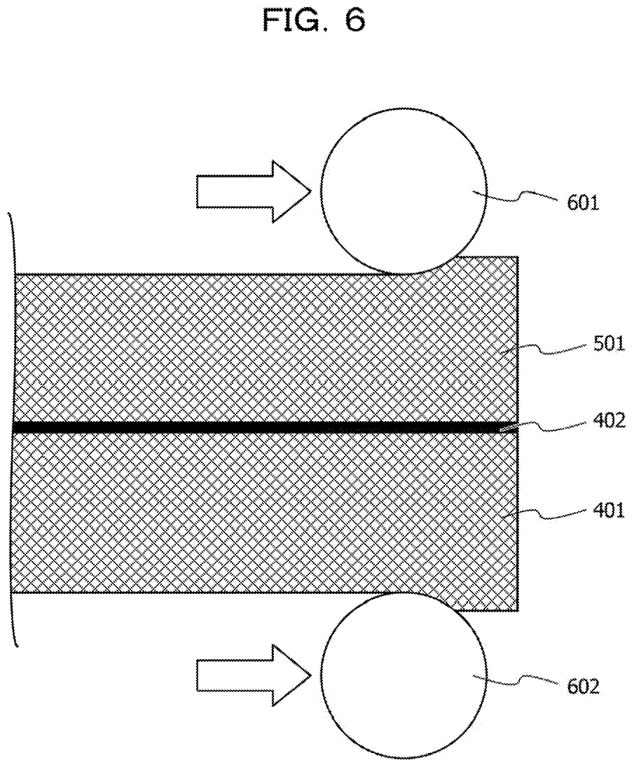

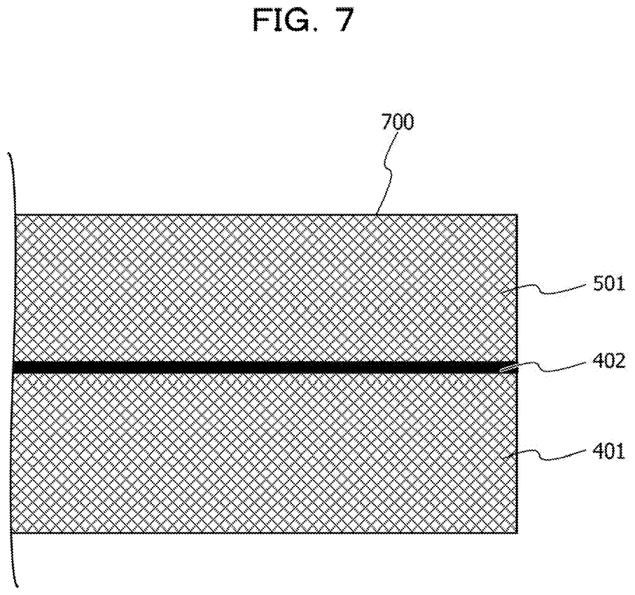

Next, as illustrated in FIG. 6, the first gold-tin sheet 401, the barrier layer 402 and the second gold-tin sheet 501 are rolled by using rollers 601 and 602. While the rollers 601 and 602 are compressing the first gold-tin sheet 401, the barrier layer 402, and the second gold-tin sheet 501 in a laminated direction thereof (a longitudinal direction in FIG. 6), the rollers 601 and 602 move in a direction perpendicular to the laminated direction (a lateral direction in FIG. 6). As a result, as illustrated in FIG. 7, a solder sheet 700 to be the solder layer 120a illustrated in FIG. 3 may be formed.

The compression amounts of the first gold-tin sheet 401, the barrier layer 402, and the second gold-tin sheet 501 by the rollers 601 and 602 are not limited to the example illustrated in FIG. 6. For example, the rollers 601 and 602 may roll the first gold-tin sheet 401, the barrier layer 402, and the second gold-tin sheet 501 such that a total thickness of the first gold-tin sheet 401, the barrier layer 402, and the second gold-tin sheet 501 is approximately half.

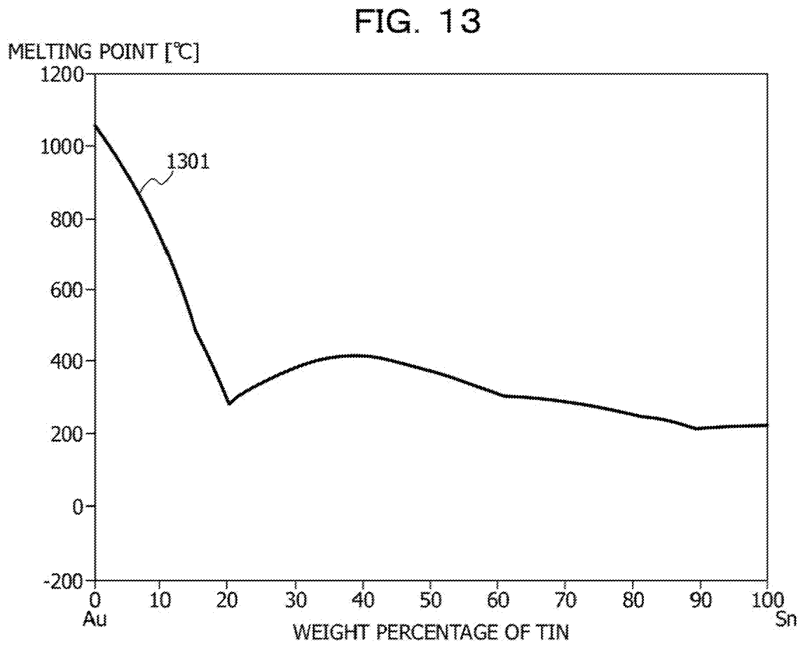

The solder sheet 700 is gold-tin solder which is excellent in heat resistance and electric conductivity, and the barrier layer 402 is included in an intermediate layer. For example, it is assumed that each of the first gold-tin sheet 401 and the second gold-tin sheet 501 is an alloy (Au80Sn20 solder) having gold content of 80% and tin content of 20%. In this case, a melting point of the first gold-tin sheet 401 and the second gold-tin sheet 501 is about 280° C. (see, for example, FIG. 13), which is higher than a melting point (about 220° C.) of silver-tin (SnAg) solder, for example. Therefore, even when bonding is performed with the silver-tin solder or the like in a subsequent process, a bonding portion of the optical device bonded by the gold-tin solder is not affected.

(Manufacturing Method of Optical Module According to Embodiment)

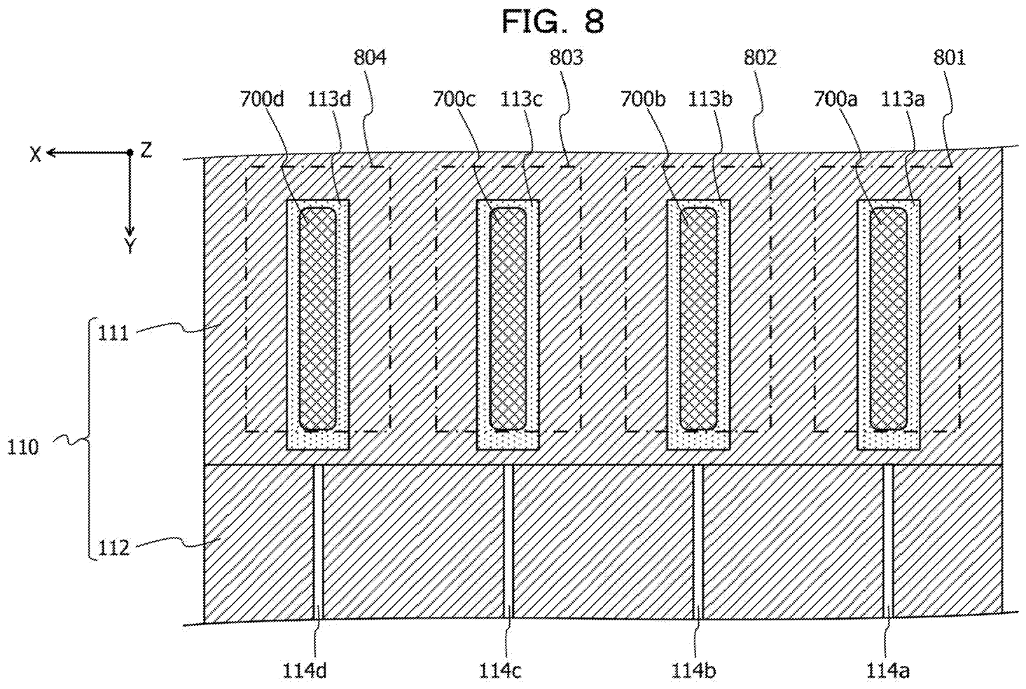

Each of FIG. 8 to FIG. 11 is a diagram illustrating an example of a manufacturing method of the optical module according to the embodiment. FIG. 8 illustrates an upper surface of the silicon photonic chip 110 illustrated in FIG. 1. Optical device mounting planned regions 801 to 804 of the silicon photonic chip 110 illustrated in FIG. 8 are areas for respectively mounting the optical devices 130a to 130d of the channels #1 to #4. The electrode pads 113a to 113d described above are arranged close to each other, and accordingly, the optical device mounting planned regions 801 to 804 are also close to each other.

First, as illustrated in FIG. 8, solder sheets 700a to 700d are respectively disposed over the electrode pads 113a to 113d. Each of the solder sheets 700a to 700d is a solder sheet similar to the solder sheet 700 illustrated in FIG. 7. The solder sheets 700a to 700d are disposed such that, for example, rear surfaces of the solder sheets 700a to 700d (a surface at a lower side in FIG. 7) are respectively in contact with the electrode pads 113a to 113d.

The solder sheets 700a to 700d may be respectively disposed without being fixed over the electrode pads 113a to 113d, or may be respectively fixed over the electrode pads 113a to 113d by punching, or the like, using a punch.

In this manner, when a plurality of optical devices (for example, the optical devices 130a to 130d) are mounted to the single silicon photonic chip 110, solder (for example, the solder sheets 700a to 700d) corresponding to the respective optical devices is first provided. The optical devices are mounted one by one in this state. This is because it is difficult to simultaneously mount a plurality of optical devices because high accuracy is required for bonding of the optical devices. For example, in the case where each of the optical devices 130a to 130d is a single mode semiconductor laser, accuracy that is equal to or less than ±0.5 [μm] is required for bonding of the optical devices 130a to 130d.

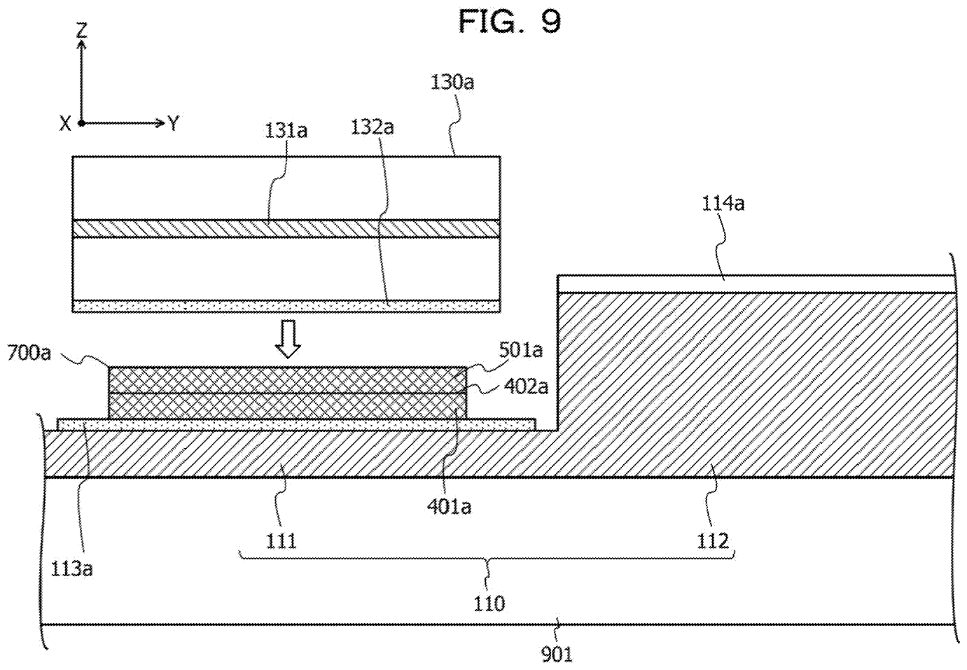

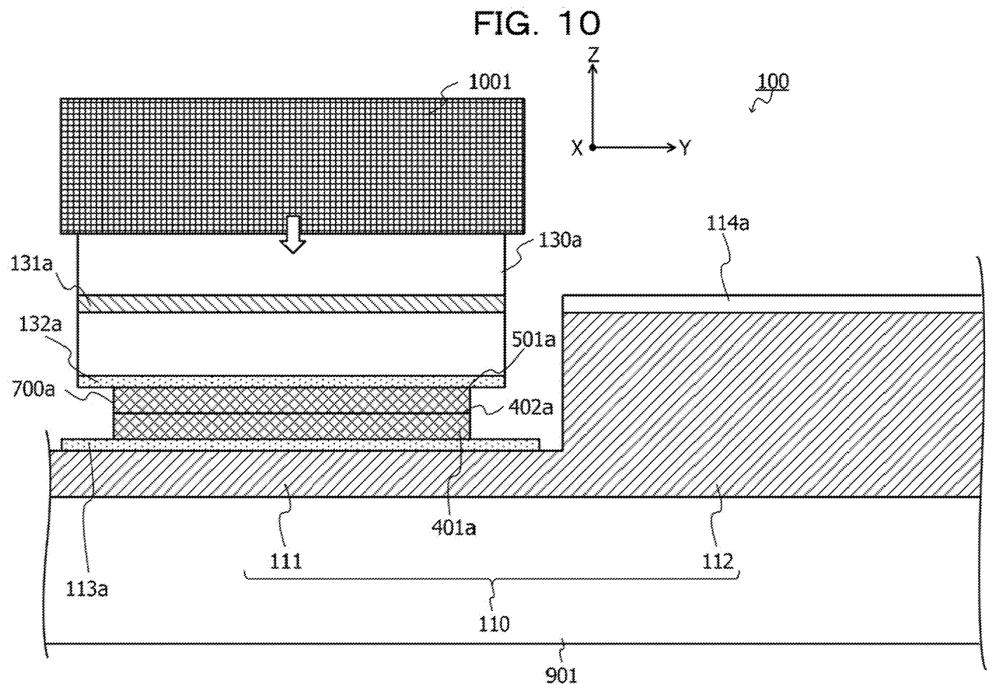

Each of FIG. 9 and FIG. 10 illustrates a cross section by the YZ plane of a portion of the channel #1 in which the optical waveguide 114a and the electrode pad 113a are provided, in the silicon photonic chip 110. A first gold-tin sheet 401a in the solder sheet 700a illustrated in FIG. 9 and FIG. 10 is a portion corresponding to the first gold-tin sheet 401 illustrated in FIG. 7 in the solder sheet 700a. The barrier layer 402a is a portion corresponding to the barrier layer 402 illustrated in FIG. 7 in the solder sheet 700a. A second gold-tin sheet 501a is a portion corresponding to the second gold-tin sheet 501 illustrated in FIG. 7 in the solder sheet 700a.

In the state illustrated in FIG. 8, as illustrated in FIG. 9, the silicon photonic chip 110 is disposed over a bonding stage 901. Alternatively, the silicon photonic chip 110 may be disposed over the bonding stage 901 before the solder sheets 700a to 700d are disposed to the silicon photonic chip 110.

The bonding stage 901 is a stage for pressurizing the silicon photonic chip 110, the solder sheet 700a, and the optical device 130a, together with a bonding tool 1001 illustrated in FIG. 10. The bonding stage 901 may have a function of heating the silicon photonic chip 110.

Next, as illustrated in FIG. 9, the optical device 130a is disposed over the solder sheet 700a such that a front surface of the solder sheet 700a disposed over the electrode pad 113a and the electrode pad 132a of the optical device 130a are in contact with each other.

Next, as illustrated in FIG. 10, the bonding tool 1001 is disposed over the optical device 130a. The bonding tool 1001 performs heating of the optical device 130a and pressurizing of the optical device 130a to the side of the silicon photonic chip 110.

For example, at this time, positional alignment between the light emitting portion 131a of the optical device 130a and the optical waveguide 114a is performed. This positional alignment may be performed, for example, by putting alignment marks to the optical device 130a and the silicon photonic chip 110, and by moving the optical device 130a such that a positional relationship between the alignment marks becomes a predetermined positional relationship. As a result, as illustrated in FIG. 1, the optical device 130a and the silicon photonic chip 110 are in a positional relationship in which light emitted from the light emitting portion 131a of the optical device 130a is coupled to the optical waveguide 114a.

By heating the optical device 130a by using the bonding tool 1001, the solder sheet 700a that is in contact with the optical device 130a is also heated. Temperature of the solder sheet 700a is made to be temperature equal to or higher than a melting point of the first gold-tin sheet 401a and the second gold-tin sheet 501a by the heating using the bonding tool 1001. As an example, when the melting point of the first gold-tin sheet 401a and the second gold-tin sheet 501 is about 280° C., as described above, the temperature of the solder sheet 700a is set to about 300° C. As a result, the first gold-tin sheet 401a and the second gold-tin sheet 501a may be melted.

At this time, the temperature of the solder sheet 700a may be equal to or higher than the melting point of the first gold-tin sheet 401a and the second gold-tin sheet 501a, and may be lower than a melting point of the barrier layer 402a. It is possible to avoid that the barrier layer 402a is melted and mixed with gold and tin included in the first gold-tin sheet 401a and the second gold-tin sheet 501a. It is possible to avoid that compositions of the first gold-tin sheet 401a and the second gold-tin sheet 501a change depending on the material (for example, nickel) of the barrier layer 402a.

Next, the solder sheet 700a is cooled such that the temperature of the solder sheet 700a is lower than the melting point of the first gold-tin sheet 401a and the second gold-tin sheet 501a, thereby solidifying the first gold-tin sheet 401a and the second gold-tin sheet 501a. Thus, the first gold-tin sheet 401a is bonded to the electrode pad 113a, and the second gold-tin sheet 501a is bonded to the electrode pad 132a. The solder sheet 700a may be cooled by, for example, stopping the heating by the bonding tool 1001 or weakening the heating by the bonding tool 1001.

As the bonding tool 1001 heats and cools the solder sheet 700a, as described above, the solder sheet 700a becomes the solder layer 120a illustrated in FIG. 1 and FIG. 3. The first gold-tin sheet 401a becomes the first gold-tin layer 121a illustrated in FIG. 1 and FIG. 3. The barrier layer 402a becomes the barrier layer 122a illustrated in FIG. 1 and FIG. 3. The second gold-tin sheet 501a becomes the second gold-tin layer 123a illustrated in FIG. 1 and FIG. 3. As a result, as illustrated in FIG. 1, the optical device 130a is bonded to the silicon photonic chip 110 with the solder layer 120a interposed therebetween.

Although a process of heating the solder sheet 700a by the bonding tool 1001 has been described, when the bonding stage 901 has a function of heating, the solder sheet 700a may be heated by using the bonding stage 901. Alternatively, heating may be performed by using both the bonding tool 1001 and the bonding stage 901. The heating of the solder sheet 700a by the bonding stage 901 is performed by heat of the bonding stage 901 being transmitted to the solder sheet 700a through the silicon photonic chip 110.

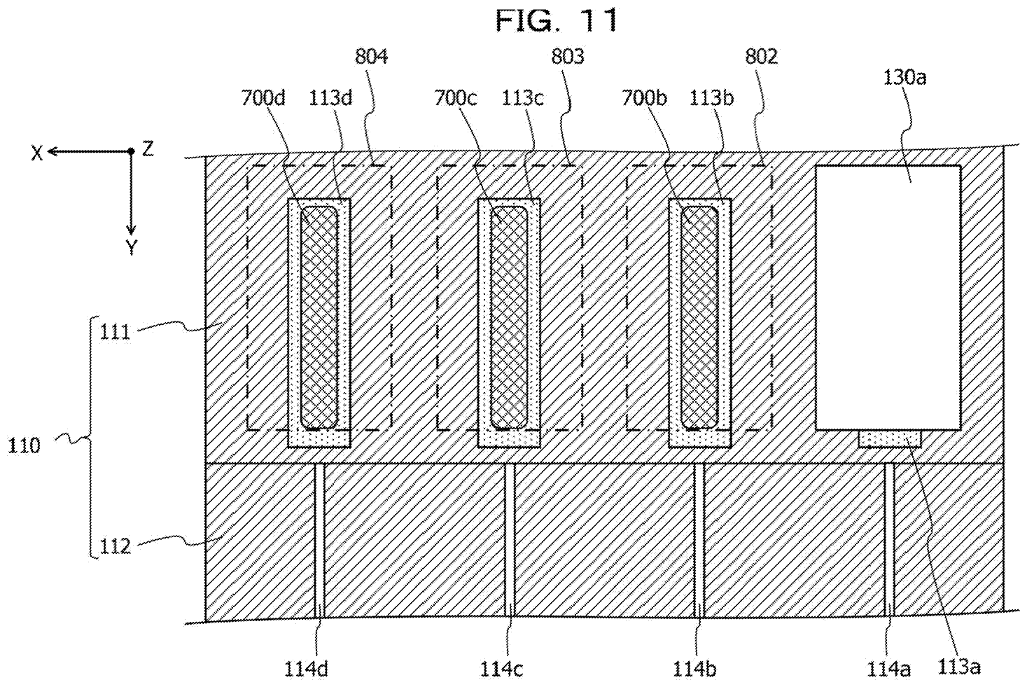

FIG. 11 illustrates the upper surface of the silicon photonic chip 110 after processes illustrated in FIG. 9 and FIG. 10. As illustrated in FIG. 11, by the processes illustrated in FIG. 9 and FIG. 10, the optical device 130a of the channel #1 may be mounted in the optical device mounting planned region 801 of the silicon photonic chip 110 as illustrated in FIG. 8.

Next, the optical device 130b is mounted in the optical device mounting planned region 802 of the silicon photonic chip 110 by the same processes as those illustrated in FIG. 9 and FIG. 10. Next, the optical device 130c is mounted in the optical device mounting planned region 803 of the silicon photonic chip 110 by the same processes as those illustrated in FIG. 9 and FIG. 10. Next, the optical device 130d is mounted in the optical device mounting planned region 804 of the silicon photonic chip 110 by the same processes as those illustrated in FIG. 9 and FIG. 10.

Thus, the optical module 100 (see FIG. 1 and FIG. 2) in which the optical devices 130a to 130d of the channels #1 to #4 are mounted to the silicon photonic chip 110 may be manufactured. After mounting the optical devices 130a to 130d to the silicon photonic chip 110, the bonding stage 901 and the bonding tool 1001 are removed from the optical module 100.

(Distribution of Gold and Tin in Solder Sheet According to Embodiment)

FIG. 12 is a cross-sectional view illustrating an example of distribution of gold and tin in the solder sheet according to the embodiment. In FIG. 12, the same portions as those illustrated in FIG. 7 and FIG. 8 are denoted by the same reference signs and descriptions thereof will be omitted.

FIG. 12 illustrates a cross section by the YZ plane of a portion of the channel #2 where the electrode pad 113b is provided, in the optical device mounting portion 111 of the silicon photonic chip 110 illustrated in FIG. 8. FIG. 12 illustrates distribution of gold and tin in the solder sheet 700b of the channel #2 immediately after the optical device 130a of the channel #1 is mounted to the silicon photonic chip 110 by heating and cooling the solder sheet 700a.

A first gold-tin sheet 401b illustrated in FIG. 12 is a portion corresponding to the first gold-tin sheet 401 illustrated in FIG. 7 in the solder sheet 700b. A barrier layer 402b illustrated in FIG. 12 is a portion corresponding to the barrier layer 402 illustrated in FIG. 7 in the solder sheet 700b. A second gold-tin sheet 501b illustrated in FIG. 12 is a portion corresponding to the second gold-tin sheet 501 illustrated in FIG. 7 in the solder sheet 700b.

In the first gold-tin sheet 401b and the second gold-tin sheet 501b illustrated in FIG. 12, a portion in which lattice-like hatching is performed is a portion in which a main component is tin, and a portion in which lattice-like hatching is not performed is a portion in which a main component is gold.

When the solder sheet 700a of the channel #1 described in FIG. 10 is heated, heat of the solder sheet 700a is transmitted to the electrode pad 113b of the channel #2 through the optical device mounting portion 111 of the silicon photonic chip 110. In the case of heating by the bonding stage 901 described above, the heat of the bonding stage 901 is transmitted to the electrode pad 113b of the channel #2 through the optical device mounting portion 111 of the silicon photonic chip 110.

Thereby, diffusion of gold atoms 1201 in the gold plating of the electrode pad 113b becomes active, and the gold atoms 1201 move to the first gold-tin sheet 401b in contact with the electrode pad 113b. As a result, as illustrated in FIG. 12, percentage of gold content in the first gold-tin sheet 401b becomes high, and a melting point of the first gold-tin sheet 401b rises. It will be described later that an increase in percentage of gold content leads to a rise in melting point (For example, see FIG. 13).

On the other hand, as described above, the barrier layer 402b having slow diffusion velocity is provided between the first gold-tin sheet 401b and the second gold-tin sheet 501b. This barrier layer 402b may suppress that the gold atoms 1201 in the gold plating of the electrode pad 113b, or the gold atoms 1201 in the first gold-tin sheet 401b in which the percentage of the gold content has been increased, move to the second gold-tin sheet 501b due to diffusion. As a result, as illustrated in FIG. 12, it is possible to suppress the increase in percentage of gold content in the second gold-tin sheet 501b and to suppress the rise in melting point of the second gold-tin sheet 501b.

Therefore, when the optical device 130b of the channel #2 is mounted by using the solder sheet 700b, it is possible to avoid that the second gold-tin sheet 501b becomes difficult to melt by heating. That is, it is possible to avoid that bonding between the solder sheet 700b and the optical device 130b becomes difficult due to melting of the second gold-tin sheet 501b. Therefore, the optical device 130b may be mounted to the silicon photonic chip 110 with high accuracy.

As described above, although the melting point of the first gold-tin sheet 401b rises due to the diffusion of the gold atoms 1201, the first gold-tin sheet 401b is bonded to the electrode pad 113b, together with the diffusion of the gold atoms 1201 due to heating the solder sheet 700a of the channel #1. Therefore, when the optical device 130b of the channel #2 is mounted, even in a case where the melting point of the first gold-tin sheet 401b rises, and the first gold-tin sheet 401b is difficult to melt, bonding between the solder sheet 700b and the electrode pad 113b has been completed, so the bonding is less influenced.

As described with reference to FIG. 12, by providing the barrier layer 402b in the solder sheet 700b, even when diffusion of gold from the electrode pad 113b is caused by heating when the optical device 130a is mounted, it is possible to avoid that it becomes difficult to mount the optical device 130b.

By also providing a barrier layer similar to the barrier layer 402b in the solder sheet 700c of the channel #3, even when diffusion of gold from the electrode pad 113c is caused by heating when the optical devices 130a and 130b are mounted, it is possible to avoid that it becomes difficult to mount the optical device 130c. By also providing a barrier layer similar to the barrier layer 402b in the solder sheet 700d of the channel #4, even when diffusion of gold from the electrode pad 113d is caused by heating when the optical devices 130a to 130c are mounted, it is possible to avoid that it becomes difficult to mount the optical device 130d.

As for the channel #1, since the optical device 130a is initially mounted among the optical devices 130a to 130d, gold of the electrode pad 113a is not diffused by heating when the optical devices of the other channels are mounted. As a result, the solder sheet 700a is not required to have a configuration including the barrier layer 402a. For example, the solder sheet 700a may be the first gold-tin sheet 401a and the second gold-tin sheet 501 directly overlapping with each other and may be a single gold-tin sheet having thickness thicker than those of the first gold-tin sheet 401a and the second gold-tin sheet 501.

In this case, each of the solder sheets 700b to 700d is an example of the first solder layer including the first gold-tin sheet 401, the barrier layer 402, and the second gold-tin sheet 501. The solder sheet 700a is an example of the second solder layer different from the first solder layer. Each of the optical devices 130b to 130d is an example of the first optical device provided over the first solder layer. Each of the optical device 130a is an example of the second optical device provided over the second solder layer.

Thus, even when the optical devices 130a to 130d are mounted to the silicon photonic chip 110 one by one, it is possible to avoid that soldering becomes difficult due to an increase in melting point of the solder layer when the second and subsequent optical devices are mounted. Therefore, it becomes possible to mount the optical devices 130a to 130d to the silicon photonic chip 110 one by one, thereby improving mounting accuracy of the optical devices 130a to 130d.

(Relationship Between Composition Ratio and Melting Point in Gold-Tin Sheet According to Embodiment)

FIG. 13 is a graph illustrating an example of a relationship between a composition ratio and a melting point in a gold-tin sheet according to the embodiment. A relationship between a composition ratio and a melting point in the second gold-tin sheet 501 of the solder sheet 700 illustrated in FIG. 7 will be described as an example, and a relationship between a composition ratio and a melting point of the first gold-tin sheet 401 of the solder sheet 700 is also similar. It is assumed that the second gold-tin sheet 501 is formed only of gold and tin.

In FIG. 13, a horizontal axis (Au, Sn) represents tin content in the second gold-tin sheet 501 by weight percentage, and a vertical axis represents the melting point [° C.] of the second gold-tin sheet 501. Melting point characteristics 1301 indicates characteristics of the melting point of the second gold-tin sheet 501 with respect to the percentage of the tin content in the second gold-tin sheet 501.

As illustrated in the melting point characteristics 1301, when the second gold-tin sheet 501 has a composition having gold content of 80% and tin content of 20%, the melting point is lowered to about 280° C., but when the percentage of the gold content is increased from the composition, the melting point becomes abruptly high. Accordingly, when the percentage of the gold content in the second gold-tin sheet 501 is increased by the diffusion of gold described above, melting of the second gold-tin sheet 501 becomes difficult, and bonding by the second gold-tin sheet 501 becomes difficult.

On the other hand, as described above, by providing the barrier layer 402 between the first gold-tin sheet 401 and the second gold-tin sheet 501, it is possible to suppress an increase in percentage of gold content in the second gold-tin sheet 501 due to diffusion of gold. Therefore, it is possible to avoid that bonding by the second gold-tin sheet 501 becomes difficult to perform.

(Forming Solder Layer of Optical Module According to Embodiment by Plating)

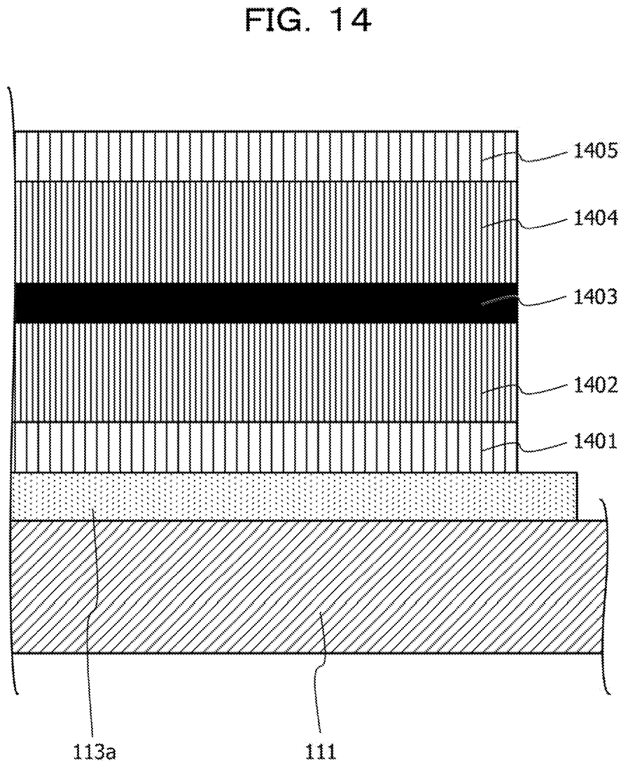

FIG. 14 is a diagram illustrating an example of forming, by plating, a solder layer of the optical module according to the embodiment. For example, as for the channel #1, although a case has been described in which the solder layer 120a is formed by providing the solder sheet 700a over the electrode pad 113a, the solder layer 120a may be formed by forming a plating layer over the electrode pad 113a.

For example, as illustrated in FIG. 14, a tin plating layer 1401 is formed over the electrode pad 113a, a gold plating layer 1402 is formed over the tin plating layer 1401, and a nickel plating layer 1403 is formed over the gold plating layer 1402. A gold plating layer 1404 is formed over the nickel plating layer 1403, and a tin plating layer 1405 is formed over the gold plating layer 1404.

The optical device 130a is disposed over the tin plating layer 1405 such that a front surface of the tin plating layer 1405 is in contact with the electrode pad 132a of the optical device 130a. Next, the bonding tool 1001 is provided over the optical device 130a to perform heating and pressurizing in the same manner as the processes illustrated in the FIG. 10.

By heating by using the bonding tool 1001, the tin plating layer 1401 and the gold plating layer 1402 are melted and mixed with each other, and thus a gold-tin alloy is formed. Similarly, by heating by using the bonding tool 1001, the gold plating layer 1404 and the tin plating layer 1405 are melted and mixed with each other, and thus a gold-tin alloy is formed. On the other hand, the nickel plating layer 1403 has a high melting point, and is not melted by heating by using the bonding tool 1001.

Next, the tin plating layer 1401, the gold plating layer 1402, the nickel plating layer 1403, the gold plating layer 1404, and the tin plating layer 1405 are cooled. As a result, the gold-tin alloy formed by mixing the tin plating layer 1401 and the gold plating layer 1402 is solidified to become the first gold-tin layer 121a illustrated in FIG. 1 and FIG. 3.

Similarly, a gold-tin alloy formed by mixing the nickel plating layer 1403 and the tin plating layer 1405 is solidified to become the second gold-tin layer 123a illustrated in FIG. 1 and FIG. 3. The nickel plating layer 1403 becomes the barrier layer 122a illustrated in FIG. 1 and FIG. 3. Therefore, the solder layer 120a illustrated in FIG. 1 and FIG. 3 is formed, and the electrode pad 113a and the electrode pad 132a are bonded with the solder layer 120a interposed therebetween.

In the example illustrated in FIG. 14, the gold plating layer and the tin plating layer may be exchanged. For example, the gold plating layer 1402 may be formed over the electrode pad 113a, the tin plating layer 1401 may be formed over the gold plating layer 1402, and the nickel plating layer 1403 may be formed over the tin plating layer 1401. The tin plating layer 1405 may be formed over the nickel plating layer 1403, and the gold plating layer 1404 may be formed over the tin plating layer 1405.

Although a case has been described in which the barrier layer 122a of the channel #1 is formed by the plating layer, the barrier layers of the channels #2 to #4 may be formed by plating layers in the same manner as the barrier layer 122a.

In this manner, in the optical module according to the embodiment, the first gold-tin layer formed over the semiconductor chip, the barrier layer formed over the first gold-tin layer and having slow diffusion velocity into tin, and the second gold-tin layer formed over the barrier layer are included in a bonding layer between the semiconductor chip and the optical device.

Such an optical module is manufactured in the following manner. That is, a solder layer is first disposed over a semiconductor chip. This solder layer includes a first gold-tin layer formed over the semiconductor chip and containing gold and tin as main components, a barrier layer formed over the first gold-tin layer and having slow diffusion velocity into tin, and a second gold-tin layer formed over the barrier layer and having gold and tin as main components.

Next, an optical device is disposed over the disposed solder layer, and the solder layer is heated and cooled. Thereby, soldering of the optical device over the semiconductor chip may be performed to manufacture the optical module described above.

In the above manufacturing process, when a plurality of optical devices is soldered one by one in a state where solder layers corresponding to the plurality of optical devices are disposed, by heating during soldering of a certain first optical device, gold is diffused into a solder layer corresponding to another second optical device. This diffusion of gold is caused, for example, by heating of the electrode pad containing gold and formed over the semiconductor chip.

Since the barrier layer having slow diffusion velocity into tin is provided in the solder layer corresponding to the second optical device, it is possible to suppress diffusion of gold into the second gold-tin layer in the solder layer corresponding to the second optical device. Accordingly, it is possible to suppress that a melting point of the second gold-tin layer in the solder layer corresponding to the second optical device is increased, thereby avoiding that soldering of the second optical device to the semiconductor chip becomes difficult.

Therefore, according to the manufacturing process of the embodiment, even when a plurality of optical devices is mounted to the semiconductor chip one by one, it is possible to avoid that soldering becomes difficult due to an increase in melting point of the solder layer when the second and subsequent optical devices are mounted. Therefore, the plurality of optical devices may be mounted to the semiconductor chip one by one, thereby improving mounting accuracy of each optical device.

In the optical module according to the embodiment, since the optical device is mounted to the semiconductor chip with high accuracy as described above, optical coupling loss between the optical waveguide and the optical device formed over the semiconductor chip, for example, is small, so that optical communication with high performance is possible.

A melting point of the barrier layer may be higher than each of melting points of the first gold-tin layer and the second gold-tin layer. Thus, even when the first gold-tin layer of the solder layer corresponding to another second optical device not mounted is melted by heating during soldering of a certain first optical device, it is possible to avoid that the barrier layer of the solder layer corresponding to the second optical device is melted. Accordingly, an action of the barrier layer as a barrier may be maintained.

However, the melting point of the barrier layer may be lower than each of melting points of the first gold-tin layer and the second gold-tin layer. In this case, when soldering of the certain first optical device is performed, heating is performed such that the barrier layer of the solder layer corresponding to the other second optical device not mounted is not melted. In this manner, even when the melting point of the barrier layer is low, the action of the barrier layer as the barrier may be maintained.

(Optical Communication Device According to Embodiment)

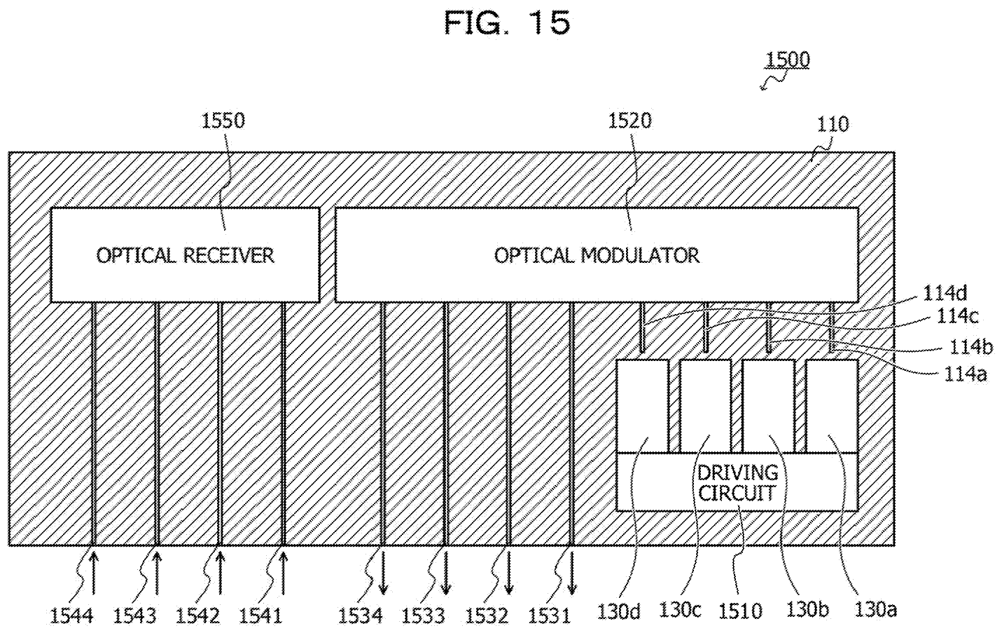

FIG. 15 is a top view illustrating an example of an optical communication device according to the embodiment. An optical communication device 1500 illustrated in FIG. 15 is an optical communication device using the optical module 100 described above. In the example illustrated in FIG. 15, the optical communication device 1500 has channels #1 to #4 as transmission channels, and has channels #5 to #8 as reception channels. For example, the optical communication device 1500 includes the silicon photonic chip 110 and the optical devices 130a to 130d.

The silicon photonic chip 110 of the optical communication device 1500 is formed with a driving circuit 1510, the optical waveguides 114a to 114d, an optical modulator 1520, optical waveguides 1531 to 1534, optical waveguides 1541 to 1544, and an optical receiver 1550.

The driving circuit 1510 includes, for example, the electrode pads 113a to 113d illustrated in FIG. 2, and drives the optical devices 130a to 130d by supplying drive current to the optical devices 130a to 130d through the electrode pads 113a to 113d, respectively.

The optical devices 130a to 130d oscillate laser light by the drive current supplied from the driving circuit 1510 through the electrode pads 113a to 113d, respectively, and emit the oscillated laser light to the optical waveguides 114a to 114d, respectively. The optical waveguides 114a to 114d propagate the laser light respectively emitted from the optical devices 130a to 130d and emit the laser light to the optical modulator 1520.

The optical modulator 1520 modulates the laser light emitted from each of the optical waveguides 114a to 114d, and outputs the optical signal obtained by the modulation to the respective optical waveguides 1531 to 1534. Each of the optical waveguides 1531 to 1534 propagates the laser light emitted from the optical modulator 1520 and sends the laser light to the outside of the silicon photonic chip 110. Thus, the respective optical signals of the channels #1 to #4 are transmitted to a partner device of the optical communication device 1500.

The optical signals of the channels #5 to #8 transmitted from the partner device of the optical communication device 1500 are respectively incident to the optical waveguides 1541 to 1544. Each of the optical waveguides 1541 to 1544 propagates the incident optical signal and emits the optical signal to the optical receiver 1550. The optical receiver 1550 receives the respective optical signals of the channels #1 to #4 emitted from the optical waveguides 1541 to 1544. For example, the optical receiver 1550 includes an optical demodulator for demodulating each of the optical signals of the channels #1 to #4, a light reception portion for receiving each optical signal demodulated by the optical demodulator, a decoding circuit for decoding each signal obtained by the light reception portion, and the like.

The driving circuit 1510, the optical waveguides 114a to 114d, 1531 to 1534, and 1541 to 1544, and the optical receiver 1550 described above may be formed to the silicon photonic chip 110, for example, by silicon photonics. On the other hand, it is difficult to make the silicon photonic chip 110 emit light because of material properties thereof, and as for the optical devices 130a to 130d that emit light, it is difficult to form the silicon photonic chip 110 by silicon photonics. Therefore, the optical devices 130a to 130d are mounted over the silicon photonic chip 110 with solder as described above.

Although the optical communication device 1500 capable of transmitting and receiving an optical signal has been described in FIG. 15, an optical communication device may be applicable in which the optical waveguides 1541 to 1544, and the optical receiver 1550 are omitted from the optical communication device 1500 illustrated in FIG. 15, for example, and that is capable of transmitting an optical signal.

As described above, in the optical communication device according to the embodiment, the optical device may be mounted to the semiconductor chip with high accuracy in the same manner as the optical module according to the embodiment described above. Therefore, optical coupling loss between the optical waveguide and the optical device that are formed over the semiconductor chip is small, so that optical communication with high performance is possible.

In the above-described optical module 100 and the optical communication device 1500, the semiconductor laser is mounted to the silicon photonic chip 110 as an optical device, but the optical device mounted to the silicon photonic chip 110 is not limited to the semiconductor laser. For example, a semiconductor optical amplifier (SOA) may be mounted to the silicon photonic chip 110 in place of the semiconductor laser. That is, the optical device to be mounted to the silicon photonic chip 110 may be, for example, various optical devices that emit light.

Although the optical module 100 is a four-channel optical transmission module, the number of channels in the optical module 100 may be any number of channels, for example, two or more channels.

As described above, according to the optical module, the optical communication device, and the manufacturing method thereof, it is possible to improve the mounting accuracy of the optical device with respect to the semiconductor chip.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An optical module comprising:
a semiconductor chip;
a first gold-tin layer formed over the semiconductor chip and having gold and tin as main components;
a barrier layer formed over the first gold-tin layer, having slower diffusion velocity into tin than diffusion velocity of gold into tin, and having electric conductivity;
a second gold-tin layer formed over the barrier layer and having gold and tin as main components; and
an optical device provided over the second gold-tin layer.

2. The optical module according to claim 1, wherein
an electrode pad containing gold is formed over the semiconductor chip, and
the first gold-tin layer is formed over the electrode pad.

3. The optical module according to claim 1, further comprising:
a first solder layer formed over the semiconductor chip and including the first gold-tin layer, the barrier layer, and the second gold-tin layer;
a second solder layer formed over the semiconductor chip and being different from the first solder layer;
an optical device provided over the first solder layer; and
an optical device provided over the second solder layer and being different from the optical device.

4. The optical module according to claim 1, wherein
a melting point of the barrier layer is higher than each of melting points of the first gold-tin layer and the second gold-tin layer.

5. The optical module according to claim 1, wherein
the semiconductor chip is a silicon photonic chip in which an optical waveguide is formed, and
the optical device is a semiconductor laser or a semiconductor optical amplifier configured to emit light to the optical waveguide.

6. The optical module according to claim 1, wherein
the barrier layer is made of at least any one of nickel, titanium, and tungsten.

7. An optical communication device comprising:
a semiconductor chip in which an optical waveguide is formed;
a first gold-tin layer formed over the semiconductor chip and having gold and tin as main components;
a barrier layer formed over the first gold-tin layer, having slower diffusion velocity into tin than diffusion velocity of gold into tin, and having electric conductivity;
a second gold-tin layer formed over the barrier layer and having gold and tin as main components;
an optical device provided over the second gold-tin layer and configured to emit light to the optical waveguide; and
a driving circuit configured to drive the optical device.

8. A manufacturing method comprising:
disposing a first solder layer including
a first gold-tin layer formed over a semiconductor chip and containing gold and tin as main components,
a barrier layer formed over the first gold-tin layer, having slower diffusion velocity into tin than diffusion velocity of gold into tin, and having electric conductivity, and
a second gold-tin layer formed over the barrier layer and having gold and tin as main components;
disposing a first optical device over the first solder layer; and
soldering the first optical device over the semiconductor chip by heating and cooling the first solder layer.

9. The manufacturing method according to claim 8, wherein
the first solder layer is formed by forming the barrier layer over a gold-tin sheet having gold and tin as main components, and by disposing a sheet having gold and tin as main components over the barrier layer.

10. The manufacturing method according to claim 8, further comprising:
when the first solder layer is disposed,
forming the first gold-tin layer by forming plating having gold as a main component and plating having tin as a main component over the semiconductor chip;
forming the barrier layer by forming plating having slower diffusion velocity into tin than diffusion velocity of gold into tin, and having electric conductivity over the first solder layer; and
forming the second gold-tin layer by forming plating having gold as a main component and plating having tin as a main component over the barrier layer.

11. The manufacturing method according to claim 8, further comprising:
disposing the second solder layer different from the first solder layer, and the first solder layer over the semiconductor chip;
disposing a second optical device different from the first optical device over the second solder layer;
soldering the second optical device over the semiconductor chip by heating and cooling the second solder layer;
disposing the first optical device over the first solder layer; and
soldering the first optical device over the semiconductor chip by heating and cooling the first solder layer.
